(19) United States
(12) Patent Application Publication
(10) Pub. No.: US 2018/0212183 A1
(43) Pub. Date: Jul. 26, 2018

(54) DISPLAY DEVICE

(71) Applicant: Japan Display Inc., Tokyo (JP)

(72) Inventor: Chunche Ma, Tokyo (JP)

(21) Appl. No.: 15/875,164

(22) Filed: Jan. 19, 2018

(30) Foreign Application Priority Data
Jan. 25, 2017 (JP) 2017-010967

(51) Int. Cl. H01L 51/52; H01L 27/32

(52) U.S. Cl. CPC H01L 51/5203; G09G 2310/0264; H01L 27/3211

(57) ABSTRACT

Disclosed is a display device having a first light-emitting element and a second light-emitting element. The first light-emitting element and the second light-emitting element each possess: a first electrode; a second electrode over and in contact with the first electrode; an electroluminescence layer over the second electrode; and a third electrode over the electroluminescence layer, the third electrode being shared by the first light-emitting element and the second light-emitting element. The first electrode of the first light-emitting element and the first electrode of the second light-emitting element respectively include a first metal and a second metal different from the first metal.

### CROSS REFERENCE TO RELATED APPLICATIONS

This application is based on and claims the benefit of priority from the prior Japanese Patent Application No. 2017-010967, filed on Jan. 25, 2017, the entire contents of which are incorporated herein by reference.

### FIELD

An embodiment of the present invention relates to a light-emitting element, a display device including the light-emitting element, and a manufacturing method of the display device.

### BACKGROUND

An EL (Electroluminescence) display device is represented as an example of a display device. An EL display device has a light-emitting element in each of a plurality of pixels formed over a substrate. A light-emitting element possesses an electroluminescence layer between a pair of electrodes (cathode and anode) and is driven by supplying a current to the pair of electrodes. A color provided by a light-emitting element is mainly determined by an emission wavelength of an emission material in an electroluminescence layer, and a variety of emission colors can be obtained by appropriately selecting an emission material. Full-color display can be realized by arranging, over a substrate, a plurality of light-emitting elements giving different emission colors. When an electroluminescence layer is mainly composed of an organic compound, a light-emitting element is called an organic light-emitting element or an organic EL element, and a display device including these elements is also called an organic EL display device.

An emission color of a light-emitting element can be also adjusted by utilizing a light-interference effect in a light-emitting element. For example, Japanese Patent Application Publication No. 2014-132525 discloses a method to improve efficiency of a light-emitting element in which light obtained from an electroluminescence layer is resonated between a pair of electrodes to increase luminance in a front direction.

### SUMMARY

An embodiment of the present invention is a display device having a first light-emitting element and a second light-emitting element. The first light-emitting element and the second light-emitting element each possess: a first electrode; a second electrode over and in contact with the first electrode; an electroluminescence layer over the second electrode; and a third electrode over the electroluminescence layer, the third electrode being shared by the first light-emitting element and the second light-emitting element. The first electrode of the first light-emitting element and the first electrode of the second light-emitting element respectively include a first metal and a second metal different from the first metal.

An embodiment of the present invention is a display device having a first light-emitting element and a second light-emitting element. The first light-emitting element and the second light-emitting element each possess: a first electrode; a second electrode over and in contact with the second electrode; an electroluminescence layer over the second electrode; and a third electrode over the electroluminescence layer, the third electrode being shared by the first light-emitting element and the second light-emitting element. The first electrodes of the first light-emitting element and the second light-emitting elements are different in thickness from each other.

### BRIEF DESCRIPTION OF DRAWINGS

FIG. 1A to FIG. 10 are schematic cross-sectional views of a display device according to an embodiment of the present invention;

FIG. 2 is a schematic top view of a display device according to an embodiment of the present invention;

FIG. 3A to FIG. 3C are schematic cross-sectional views of a display device according to an embodiment of the present invention;

FIG. 4A and FIG. 4B are diagrams showing characteristics of a display device according to an embodiment of the present invention;

FIG. 5A and FIG. 5B are schematic cross-sectional views of a display device according to an embodiment of the present invention;

FIG. 6 is a schematic cross-sectional view of a display device according to an embodiment of the present invention;

FIG. 7A to FIG. 7C are schematic cross-sectional views of a display device according to an embodiment of the present invention;

FIG. 8 is a schematic perspective view of a display device according to an embodiment of the present invention;

FIG. 9 is a schematic cross-sectional view of a display device according to an embodiment of the present invention;

FIG. 10A to FIG. 100 are schematic cross-sectional views for explaining a manufacturing method of a display device according to an embodiment of the present invention;

FIG. 11A to FIG. 11C are schematic cross-sectional views for explaining a manufacturing method of a display device according to an embodiment of the present invention;

FIG. 12A and FIG. 12B are schematic cross-sectional views for explaining a manufacturing method of a display device according to an embodiment of the present invention;

FIG. 13A and FIG. 13B are schematic cross-sectional views for explaining a manufacturing method of a display device according to an embodiment of the present invention;

FIG. 14A and FIG. 14B are schematic cross-sectional views for explaining a manufacturing method of a display device according to an embodiment of the present invention;

FIG. 15A and FIG. 15B are schematic cross-sectional views for explaining a manufacturing method of a display device according to an embodiment of the present invention;

FIG. 16A and FIG. 16B are schematic cross-sectional views for explaining a manufacturing method of a display device according to an embodiment of the present invention; and

FIG. 17 is a schematic cross-sectional view for explaining a manufacturing method of a display device according to an embodiment of the present invention.

### DESCRIPTION OF EMBODIMENTS

Hereinafter, the embodiments of the present invention are explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate.

In the present invention, when a plurality of films is formed by processing one film, the plurality of films may have functions or rules different from each other. However, the plurality of films originates from a film formed as the same layer in the same process and has the same layer structure and the same material. Therefore, the plurality of films is defined as films existing in the same layer.

In the specification and the scope of the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

### First Embodiment

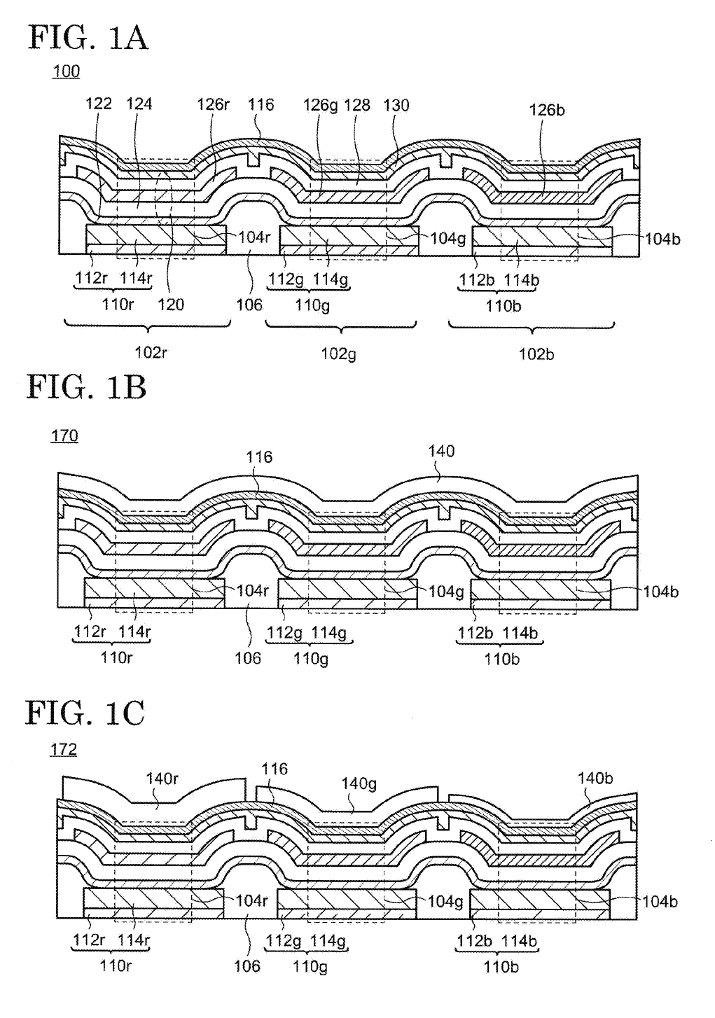

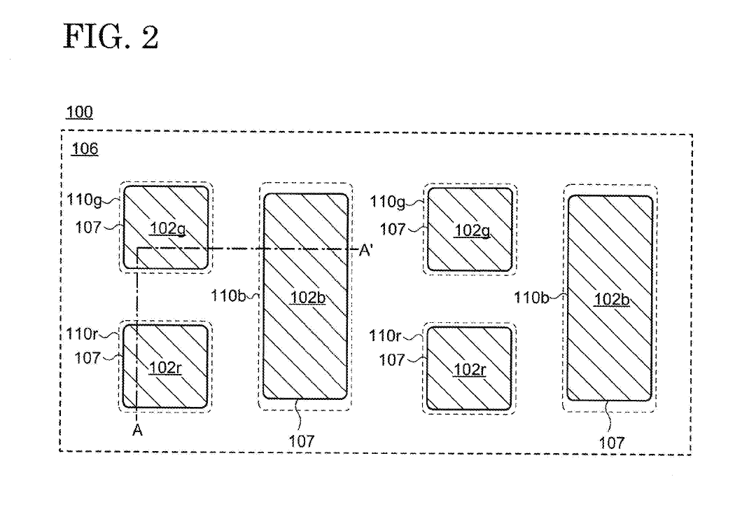

FIG. 1A and FIG. 2 are respectively schematic cross-sectional and top views of a display device 100 according to the First Embodiment. A cross-section along a chain line A-A′ of FIG. 2 corresponds to FIG. 1A. As shown in FIG. 2, the display device 100 has a plurality of pixels 102. Three adjacent pixels, i.e., a first pixel 102b, a second pixel 102g, and a third pixel 102r, are illustrated in FIG. 2. These first to third pixels 102b, 102g, and 102r may be configured to provide different emission colors from one another. For example, three kinds of pixels 102 giving the three primary colors of red, green, and blue colors may be arranged, by which full-color display can be accomplished. The following explanation is given for a case where the first pixel 102b, the second pixel 102g, and the third pixel 102r give blue, green, and red colors, respectively. However, the structure of the display device 100 is not limited thereto as long as the display device 100 is configured so that the adjacent two pixels 102 provide different emission colors. For example, the display device 100 may be configured so that a wavelength of light emission obtained from the second pixel 102g is longer than that obtained from the first pixel 102b and shorter than that obtained from the third pixel 102r. Additionally, the emission colors are not limited to three kinds of colors. For example, the emission colors may be the four colors of blue, green, red, and white. Here, a wavelength of light emission corresponds to a peak wavelength of emission obtained from the pixel 102, an emission peak wavelength of a light-emitting element 104 (described below) disposed in each pixel 102, or an emission peak wavelength of an emission material in the light-emitting element 104.

In the present specification, the pixels 102 collectively mean the first pixel 102b, the second pixel 102g, and the third pixel 102r. The same is applied to other reference numbers without a subscript such as b, g, and r.

Light-emitting elements 104b, 104g, and 104r are disposed in the first to third pixels 102b, 102g, and 102r, respectively (FIG. 1A). Each of the light-emitting elements 104b, 104g, and 104r is structured by a first electrode 110, an electroluminescence layer 120 over the first electrode 110, and a second electrode 116 over the electroluminescence layer 120. Hereinafter, the light-emitting elements 104b, 104g, and 104r are expressed as a first light-emitting element, a second light-emitting element, and a third light-emitting element, respectively.

The first electrode 110 is disposed in each pixel 102 and configured to be independently applied with a potential. On the other hand, the second electrode 116 is continuously formed over and shared by the plurality of pixels 102 and the plurality of light-emitting elements 104. The display device 100 is configured so that a constant potential is applied to the second electrode 116. One of the first electrode 110 and the second electrode 116 functions as an anode, and the other serves as a cathode. In the present embodiment, an explanation is given to an example in which the first electrode 110 and the second electrode 116 respectively function as an anode and a cathode.

The first electrode 110 of each light-emitting element 104 possesses two layers. Specifically, the first electrode 110 of each light-emitting element 104 has a reflective electrode 112 including a metal capable of reflecting emission which is obtained from the electroluminescence layer 120 and includes visible light as well as an electrode (hereinafter, referred to as a transparent electrode) 114 which is located over the reflective electrode 112 and able to transmit the emission. More specifically, the first electrode 110b of the first pixel 102b has a reflective electrode 112b and a transparent electrode 114b, the first electrode 110g of the second pixel 102g has a reflective electrode 112g and a transparent electrode 114g, and the first electrode 110r of the third pixel 102r has a reflective electrode 112r and a transparent electrode 114r. In each of the light-emitting elements 104, the reflective electrode 112 is in direct contact with and electrically connected to the transparent electrode 114. Note that the reflective electrode 112, the transparent electrode 114, and the second electrode 116 may be independently recognized as an electrode. In this case, they are respectively called a first electrode, a second electrode, and a third electrode.

As a metal included in the reflective electrode 112, a metal such as aluminum, silver, copper, gold, molybdenum, tungsten, tantalum, and nickel and an alloy thereof are represented and are selected so that the metals included in the reflective electrodes 112b, 112g, and 112r are different from one another or one of the metals is different from the other two metals. At least one of the reflective electrodes 112b, 112g, and 112r may be structured by stacked films of these metals.

The metals included in the reflective electrodes 112b, 112g, and 112r may be selected from a variety of metals so that a reflectance of the reflective electrode 112g is lower than that of the reflective electrode 112b and equal to or higher than that of the reflective electrode 112r. In other words, the reflective electrodes 112 may be configured so that the following relationship is established:

R_{1b}>R_{1g}≥R₁ᵣ

where the reflectances of the reflective electrodes 112b, 112g, and 112r are R_{1b}, R_{1g}, and R₁ᵣ, respectively. For example, the reflective electrodes 112b, 112g, and 112r may include silver, aluminum, and an alloy of molybdenum and tungsten, respectively.

The transparent electrodes 114 may include a conductive oxide capable of transmitting at least part of visible light. As a conductive oxide, indium-tin oxide (ITO), indium-zinc oxide (IZO), and the like are exemplified. Silicon may be included in the oxide.

Thicknesses of the reflective electrodes 112 may be the same or different between the first to third light-emitting elements 104b, 104g, and 104r. Similarly, thicknesses of the transparent electrodes 114 may be the same or different between the first to third light-emitting elements 104b, 104g, and 104r. When the thicknesses of the transparent electrode 114 are arranged to be the same in the all light-emitting elements 104, the manufacturing process of the display device 100 can be simplified.

The second electrode 116 may be structured as a semi-transparent and semi-reflective electrode partly reflecting and partly transmitting visible light. For example, the second electrode 116 may be formed so as to include magnesium, lithium, silver, or an alloy thereof (e.g., Mg—Ag) at a thickness which allows visible light to partly pass therethrough. The thickness thereof may be selected in a range from 5 nm to 100 nm.

A partition wall 106 is disposed between the first electrodes 110 of the adjacent pixels 102. The partition wall 106 is an insulating film and covers edge portions of the first electrodes 110. With this structure, steps caused by the edge portions of the first electrodes 110 are retrieved, and the electroluminescence layer 120 and the second electrode 116 formed thereover can be prevented from being disconnected by the steps. FIG. 2 shows the partition wall 106 and the first electrodes 110, and opening portions 107 are formed in the partition wall 106 in which the first electrode 110 of each of the pixels 102 is exposed.

The electroluminescence layer 120 is formed so as to be in contact with and cover the first electrodes 110 and the partition wall 106. The second electrode 116 is disposed so as to be in contact with the electroluminescence layer 120. In the specification and claims, the electroluminescence layer 120 means the films sandwiched by the first electrode 110 and the second electrode 116.

The structure of the electroluminescence layer 120 may be arbitrarily determined. In the display device 100 shown in FIG. 1A, the electroluminescence layer 120 includes a hole-injection layer 122, a hole-transporting layer 124, an emission layer 126, an electron-transporting layer 128, and an electron-injection layer 130. It is not necessary for the electroluminescence layer 120 to possess all these five layers, and one layer may have functions of a plurality of layers, for example. Each layer may have a single-layer structure or may be formed of stacked layers of different materials. The electroluminescence layer 120 may include a layer having another function, such as a hole-blocking layer, an electron-blocking layer, and an exciton-blocking layer.

The hole-injection layer 122 has a function to promote hole injection to the electroluminescence layer 120 from the first electrode 110. The hole-injection layer 122 may be provided so as to be in contact with the first electrodes 110 and the partition wall 106. For the hole-injection layer 122, a compound to which holes are readily injected, that is, a compound readily oxidized (i.e., electron-donating compound) can be used. In other words, a compound whose level of the highest occupied molecular orbital (HOMO) is shallow can be used. For example, an aromatic amine such as a benzidine derivative and a triarylamine, a carbazole derivative, a thiophene derivative, a phthalocyanine derivative such as copper phthalocyanine, and the like can be used. Alternatively, a polymer material such as polythiophene, polyaniline, or a derivative thereof may be used. Poly(3,4-ethylenedioxydithiophene)/poly(styrenesulfonic acid) is represented as an example. A mixture of an electron-donating compound such as the aforementioned aromatic amine, carbazole derivative, or aromatic hydrocarbon with an electron acceptor may be used. As an electron acceptor, a transition-metal oxide such as vanadium oxide and molybdenum oxide, a nitrogen-containing heteroaromatic compound, an aromatic compound having a strong electron-withdrawing group such as a cyano group, and the like are represented.

The hole-transporting layer 124 has a function to transport holes injected to the hole-injection layer 122 to the emission layer 126, and a material the same as or similar to the material usable in the hole-injection layer 122 can be used. For example, it is possible to use a material having a deeper HOMO level than that of the hole-injection layer 122 and having a difference in HOMO level from the hole-injection layer 122 by approximately 0.5 eV or less. Typically, an aromatic amine such as a benzidine derivative can be used.

The emission layer 126 may be formed with a single compound or have the so-called host-guest type structure. In the case of the host-guest type structure, a stillbene derivative, a condensed aromatic compound such as an anthracene derivative, a carbazole derivative, a metal complex including a ligand having a benzoquinolinol as a basic skeleton, an aromatic amine, a nitrogen-containing heteroaromatic compound such as a phenanthroline derivative, and the like can be used as a host material, for example. A guest functions as an emission material, and a fluorescent material such as a coumarin derivative, a pyran derivative, a quinacridone derivative, a tetracene derivative, a pyrene derivative, and an anthracene derivative, or a phosphorescent material such as an iridium-based orthometal complex can be used. When the emission layer 126 is configured with a single compound, the above host material can be used as an emission material.

As shown in FIG. 1A, the emission layer 126 may have different structures or include different emission materials between the adjacent pixels 102. With this configuration, emission colors different between the adjacent pixels 102 can be generated. The emission layer 126 in the display device 100 may be configured so that the emission wavelength of the emission material included in the emission layer 126g of the second light-emitting element 104g is shorter than that in the emission layer 126r of the third light-emitting element 104r and longer than that in the emission layer 126b of the first light-emitting element 104b. An emission wavelength of an emission material is evaluated by photoluminescence in solution or in a film state.

The electron-transporting layer 128 has a function to transport electrons injected from the second electrode 116 through the electron-injection layer 130 to the emission layer 126. For the electron-transporting layer 128, a compound readily reduced (i.e., electron-accepting compound) can be used. In other words, a compound whose level of the lowest unoccupied molecular orbital (LUMO) is deep can be used. For example, a metal complex including a ligand having a benzoquinolinol as a basic skeleton, such as tris(8-quinolinolato)aluminum and tris(4-methyl-8-quinolinolato)aluminum, a metal complex including a ligand having an oxathiazole or thiazole as a basic skeleton, and the like are represented. In addition to these metal complexes, a compound with an electron-deficient heteroaromatic ring, such as an oxadiazole derivative, a thiazole derivative, a triazole derivative, and a phenanthroline derivative, can be used.

For the electron-injection layer 130, a compound which promotes electron injection to the electron-transporting layer 128 from the second electrode 116 can be used. For example, a mixture of a compound usable in the electron-transporting layer 128 with an electron donor such as lithium or magnesium can be used. Alternatively, an inorganic compound such as lithium fluoride and calcium fluoride may be used.

In the present specification and claims, a region from an upper surface of the first electrode 110 to a bottom surface of the emission layer 126 is defined as a hole-transporting region, and a region from an upper surface of the emission layer 126 to a bottom surface of the second electrode 116 is defined as an electron-transporting region. The hole-injection layer 122 and the hole-transporting layer 124 are included in the hole-transporting region, while the electron-transporting layer 128 and the electron-injection layer 130 are included in the electron-transporting region. Therefore, the electroluminescence layer 120 is structured with the hole-transporting region, the emission layer 126, and the electron-transporting region. When a layer (e.g., the hole-transporting layer 124 or the electron-transporting layer 128) other than the emission layer 126 functions as an emission layer, the electroluminescence layer 120 is structured with the hole-transporting region and the electron-transporting region.

When a potential difference is provided between the first electrode 110 and the second electrode 116, holes and electrons are injected to the electroluminescence layer 120 from the former and the latter, respectively. Holes are transported to the emission layer 126 through the hole-injection layer 122 and the hole-transporting layer 124, while electrons are transported to the emission layer 126 through the electron-injection layer 130 and the electron-transporting layer 128. Holes and electrons are recombined in the emission layer 126, by which an excited state of the emission material included in the emission layer 126 is produced. When the excited state relaxes to a ground state, light having a wavelength corresponding to an energy difference between the excited state and the ground state is radiated and observed as the light emission from each light-emitting element 104.

Each layer included in the electroluminescence layer 120 may be formed by applying a wet-type film-formation method such as an ink-jet method, a spin-coating method, a printing method, and a dip-coating method or a dry-type film-formation method such as an evaporation method.

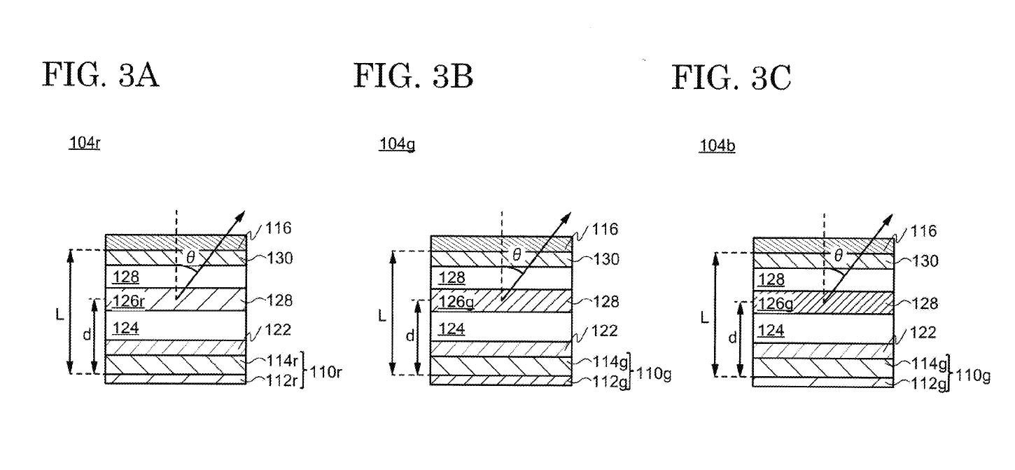

Detailed structures of the light-emitting elements 104 are illustrated in FIG. 3A to FIG. 3C. As described above, the transparent electrodes 114 and the reflective electrodes 112 are capable of respectively transmitting and reflecting the light emission from the electroluminescence layer 120. On the other hand, the second electrode 116 is able to partly reflect and partly transmit the light emission from the electroluminescence layer 120. Therefore, a resonance structure is formed by un upper surface of the reflective electrode 112 (that is, an interface between the reflective electrode 112 and the transparent electrode 114) and a bottom surface of the second electrode 116 (here, an interface between the second electrode 116 and the electron-injection layer 130). The light generated in the electroluminescence layer 120 is repeatedly reflected in the resonance structure and interferes with each other. As a result, light having a wavelength consistent with an optical distance L of the resonance structure is amplified by an interference effect while repeating reflection, whereas light having a wavelength inconsistent with the optical distance L is attenuated. Here, an optical distance is a product of a thickness by a refractive index of a layer. In the case of the display device 100, the optical distance L is a summation of the optical distances of the transparent electrode 114 and the electroluminescence layer 120. The former is a product of the thickness by a refractive index of the transparent electrode 114, while the latter is a summation of a product of a thickness by a refractive index of each layer in the electroluminescence layer 120.

When an odd multiple of one fourth of λ (λ/4) is the same as or close to the optical distance L where λ is an emission peak wavelength of the electroluminescence layer 120, the light having this wavelength λ is inconsistent with the optical distance L and attenuated. On the other hand, when an integral multiple of one half of λ (λ/2), that is, an integral multiple of a half wavelength is the same as or close to the optical distance L, the light having this wavelength λ is consistent with the optical distance L and amplified. Therefore, the thickness of each layer in the electroluminescence layer 120 and the thickness of the transparent electrode 114 may be controlled so that the optical distance L is an integral multiple of λ/2 in each of the first to third light-emitting elements 104b, 104g, and 104r. It is not necessary to arrange the optical distance L to completely match an integral multiple of λ/2, and the thickness of each layer in the electroluminescence layer 120 and the thickness of the transparent electrode 114 may be controlled so that the optical distance L ranges from 0.8 times to 1.2 times as long as an integral multiple of λ/2.

A plane in which light is mainly generated in the emission layer 126 is defined as an emission plane. The light emission is suppressed when this plane is located at an anti-node of the interfering light, while the light emission is amplified when the emission plane is located at a node. Specifically, the light emission is attenuated in a case where an optical distance d from the emission plane to the upper surface of the reflective electrode 122 or an optical distance from the emission plane to the bottom surface of the second electrode 116 is an odd multiple of one fourth of λ (λ/4). On the other hand, the light emission is amplified when the optical distance d from the emission plane to the upper surface of the reflective electrode 122 or the optical distance from the emission plane to the bottom surface of the second electrode 116 is an integral multiple of one half of λ (λ/2). Therefore, the thickness of each layer in the electroluminescence layer 120 and the thickness of the transparent electrode 114 may be controlled so that the optical distance d is an integral multiple of λ/2 in each of the first to third light-emitting elements 104b, 104g, and 104r. Note that it is not necessary to arrange the optical distance d to completely match an integral multiple of λ/2, and the thickness of each layer in the electroluminescence layer 120 and the thickness of the transparent electrode 114 may be controlled so that the optical distance d ranges from 0.8 times to 1.2 times as long as an integral multiple of λ/2. It is not always easy to determine the position of the emission plane. Hence, the thickness of each layer in the electroluminescence layer 120 and the thickness of the transparent electrode 114 may be controlled so that an optical distance from the upper surface of the reflective electrode 112 to a point arbitrarily selected in the emission layer 126 is an integral multiple of λ/2.

Moreover, a reflectance R₂ of the second electrode 116 may be adjusted by appropriately selecting a material or adjusting a thickness thereof.

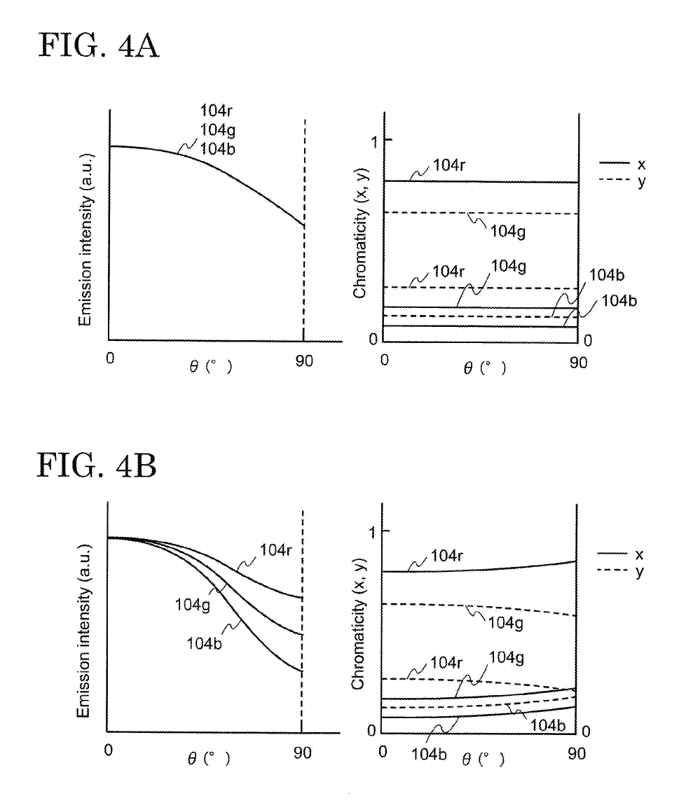

According to the traditional design concept, the resonance in a light-emitting element is controlled by appropriately adjusting these parameters, i.e., the optical distance L of the resonance structure formed in a light-emitting element, the optical distance d from the emission plane to the upper surface of the reflective electrode, the emission peak wavelength of the emission layer, and the reflectance R₂ of the second electrode, by which intensity, a full-width half-maximum, and color purity of the emission extracted from the light-emitting element 104 are controlled and improved. However, although the control of only these parameters realizes an increase of emission intensity in a front direction and a decrease of a full-width half-maximum, viewing-angle dependence is contrarily decreased, resulting in a significant reduction in luminance and a considerable change in emission color when a viewing angle is increased. Additionally, a difference in viewing-angle dependence of the emission intensity and the emission wavelength is caused between the light-emitting elements with different structures. For example, as schematically demonstrated by the left diagram of FIG. 4B, the viewing-angle dependence of the intensity of the light radiated in a direction inclined from the front direction (normal direction of the reflective electrode 112) at an angle of θ varies between the light-emitting elements 104 when the reflectances R_{1b}, R_{1g}, and R₁ᵣ of the reflective electrodes 112b, 112g, and 112r of the first to third light-emitting elements 104b, 104g, and 104r are the same (see FIG. 3A to FIG. 3C). In this diagram, for example, the angle dependence is relatively large in the first light-emitting element 104b, while that of the third light-emitting element 104r is small. In addition, the behavior of the change in emission color of the light-emitting elements, i.e., chromaticity of x and y, independently depends on the angle θ between the light-emitting elements 104 (see the right diagram in FIG. 4B). Hence, an image reproduced by the plurality of light-emitting elements 104 significantly changes in not only brightness but also color according to the angle θ.

The difference in behavior between the first to third light-emitting elements 104b, 104g, and 104r is caused by the increase in viewing-angle dependence of emission intensity with decreasing emission wavelength. The emission intensity E_{cav}(λ) of the light-emitting element 104 is expressed by the following equation:

$${\vert {E}_{cav} ( λ ) \vert}^{2} = \frac{\frac{( 1 - {R}_{2} )}{i} {\sum }_{i} [ 1 + {R}_{1} + 2 \sqrt{{R}_{1}} cos ( \frac{4 π {d}_{i} cos θ}{λ} + {Φ}_{1} ) ]}{1 + {R}_{1} {R}_{2} - 2 \sqrt{{R}_{1} {R}_{2}} cos ( \frac{4 π L cos θ}{λ} + {Φ}_{1} + {Φ}_{2} )} {\vert {E}_{nc} ( λ ) \vert}^{2}$$

where E_{nc}(λ) is the emission intensity of the light-emitting element 104 in the absence of a resonance structure, and ϕ1 and ϕ2 are wavelength-dependent phase changes on reflection at the reflective electrode 112 and the second electrode 116, respectively. Other variables are described above. As revealed by this equation, the terms including the angle θ increase with decreasing λ, resulting in the viewing-angle dependence of the emission intensity between the light-emitting elements 104 having different emission colors.

The inventor focused on a fact that the variables relating to the angle θ include not only the emission peak wavelength λ and the reflectance R₂ of the second electrode 116 but also the reflectance R₁ of the reflective electrode 112. When the reflectance R₂ of the second electrode 116 is constant, the contribution of the angle θ is decreased with decreasing reflectance R₁ of the reflective electrode 112, resulting in a reduction of the viewing-angle dependence. However, if the reflectances R_{1b}, R_{1g}, and R₁ᵣ of the reflective electrodes 112 are the same in all of the first to third light-emitting elements 104b, 104g, and 104r, the viewing-angle dependence cannot be canceled because the emission wavelengths of these light-emitting elements 104 are different. On the basis of this consideration, the inventor found that not only the viewing angle dependence can be decreased but also the behavior of the change of the emission intensity with the viewing angle can be the same in all of the light-emitting elements 104 by independently controlling the reflectances R_{1b}, R_{1g}, and R₁ᵣ of the reflective electrodes 112 so as to correspond to the emission wavelengths of the light-emitting elements 104b, 104g, and 104r.

Specifically, in addition to the parameters including the optical distance L, the optical distance d, the emission peak wavelength λ, and the reflectance R₂ of the second electrode 116, the reflectances R₁ of the reflective electrodes 112 are individually changed for the light-emitting elements 104 giving different emission colors as described above. Accordingly, as demonstrated by the left diagram in FIG. 4A, the behavior of the change of the emission intensity can be almost the same between the first to third light-emitting elements 104b, 104g, and 104r even if the angle θ is varied. Additionally, the viewing-angle dependence of the chromaticity of x and y can be reduced in each of the light-emitting elements 104 (see the right diagram in FIG. 4A). As a result, the light-emitting elements 104 with small viewing-angle dependence and excellent color purity of the emission can be provided. Moreover, the use of such light-emitting elements 104 allows production of the display device 100 having small viewing-angle dependence and high color reproducibility.

### Second Embodiment

In the present embodiment, display devices 170 and 172 with different structures from those of the display device 100 of the First Embodiment are explained. An explanation of the structures the same as those of the First Embodiment may be omitted.

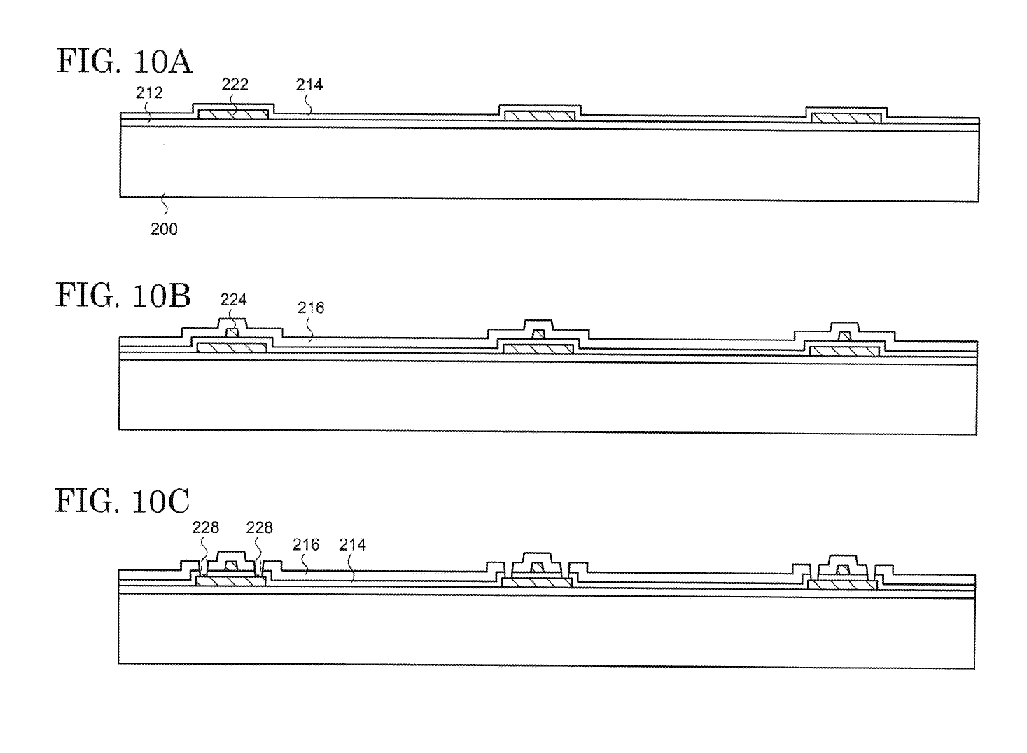

As shown in FIG. 1B and FIG. 10, the display devices 170 and 172 are different from the display device 100 in that the display devices 170 and 172 have an optical adjustment layer 140 over and in contact with the second electrode 116. The optical adjustment layer 140 has a function to control the reflectance R₂ of the second electrode 116.

A material included in the optical adjustment layer 140 can be selected from materials having a refractive index higher than that of the second electrode 116. Specifically, a material with a high transmittance and a relatively high refractive index in the visible region is represented. As an example of such a material, an organic compound is given. As an organic compound, a polymer material is representative, and a polymer material including sulfur, halogen, or phosphorous is exemplified. As a polymer including sulfur, a polymer having a substituent such as a thioether, a sulfone, and a thiophene in the main or side chain is given. As a polymer material including phosphorous, a polymer material including a phosphorous acid, a phosphoric acid, or the like in the main or side chain, a polyphosphazene, or the like is represented. As a polymer material including halogen, a polymer material including bromine, iodine, or chlorine as a substituent is exemplified. The polymer material may be intermolecularly or intramolecularly cross-linked.

As another example, an inorganic material is represented, and titanium oxide, zirconium oxide, chromium oxide, aluminum oxide, indium oxide, ITO, IZO, lead sulfide, zinc sulfide, silicon nitride, and the like are exemplified. A mixture of the inorganic compound and the polymer material may be used.

The optical adjustment layer 140 further possesses a function to allow the light passing through the second electrode 116 to interfere therein. Therefore, a thickness of the optical adjustment layer 140 may be varied between the first to third pixels 102b, 102g, and 102r. For example, as demonstrated by the display device 172 shown in FIG. 10, the optical adjustment layer 140 may be configured so that a thickness of an optical adjustment layer 140g in the second pixel 102g is larger than a thickness of an optical adjustment layer 140b in the first pixel 102b and smaller than a thickness of an optical adjustment layer 140r in the third pixel 102r. Arrangement of the optical adjustment layer 140 in such a manner enables an increase in emission efficiency and improvement of color purity of the light-emitting elements 104.

Similar to the First Embodiment, the reflectances R₁ of the reflective electrodes 112 are different between the first to third light-emitting elements 104b, 104g, and 104r in the display devices 170 and 172. Therefore, it is possible to provide the light-emitting elements 104 having low viewing-angle dependence and excellent color purity of the emitted light. Moreover, the use of such light-emitting elements 104 allows production of a display device having small viewing-angle dependence and high color reproducibility.

### Third Embodiment

In the present embodiment, display devices 174 and 176 different in structure from those of the display devices 100, 170, and 172 of the First and Second Embodiments are explained. An explanation regarding the structures the same as those of the First and Second Embodiments may be omitted.

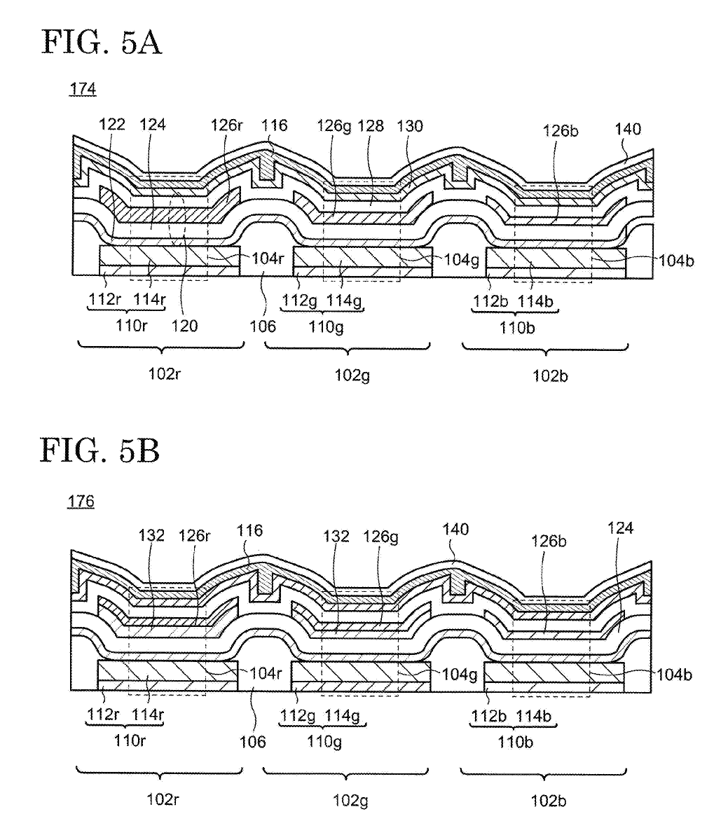

A schematic cross-sectional view of the display device 174 is shown in FIG. 5A. The display device 174 is different from the display devices 100, 170, and 172 in that thicknesses of the emission layers 126 are different between the first to third light-emitting elements 104b, 104g, and 104r by which an optimized resonance structure is formed in each light-emitting element 104.

As described in the First Embodiment, the light emission is attenuated when the optical distance d from the emission plane to the upper surface of the reflective electrode 112 is an odd multiple of one fourth of the emission peak wavelength λ (λ/4) of the emission layer 126, while the light emission is amplified when the optical distance d is an integral multiple of one half of the emission peak wavelength λ (λ/2). As demonstrated by the display device 174, the thickness of the emission layer 126 is controlled in each light-emitting element 104, by which the optical distance d can be adjusted and optimized in each pixel 102. For example, the optical adjustment can be accomplished by arranging the thickness of the emission layer 126g to be larger than the thickness of the emission layer 126b and smaller than the thickness of the emission layer 126r.

In the display device 176, thicknesses of the hole-transporting regions are further different between the pixels 102. As shown in FIG. 5B, the thickness of the hole-transporting region is adjusted by arranging an electron-blocking layer 132 between the emission layer 126 and the hole-transporting layer 124 to optimize the optical distance d in each light-emitting element 104. For example, the thicknesses of the electron-blocking layers 132 are controlled so that the thickness of the hole-transporting region of the second light-emitting element 104g is larger than that of the first light-emitting element 104b and smaller than that of the third light-emitting element 104r. With such an arrangement, amplification of the emitted light and narrowing of the spectrum can be effectively performed in each light-emitting element 104. An example is shown in FIG. 5B in which the thicknesses of the hole-transporting regions are controlled in such a manner that the first pixel 102b is not provided with the electron-blocking layer 132 while the electron-blocking layers 132 are disposed in the second pixel 102g and the third pixel 102r. The thicknesses of the hole-transporting regions may be controlled by adjusting the thicknesses of the hole-transporting layers 124 without forming the electron-blocking layer 132.

Similar to the First Embodiment, the reflectances R₁ of the reflective electrodes 112 are different between the first to third light-emitting elements 104b, 104g, and 104r in the display device 174 and 176. Therefore, it is possible to provide the light-emitting elements 104 having low viewing-angle dependence and excellent color purity of the emitted light. Moreover, the use of such light-emitting elements 104 allows production of a display device having small viewing-angle dependence and high color reproducibility.

### Fourth Embodiment

In the present embodiment, a display device 180 different in structure from those of the display devices 100, 170, 172, 174, and 176 of the First to Third Embodiments is explained. An explanation regarding the structures the same as those of the First to Third Embodiments may be omitted.

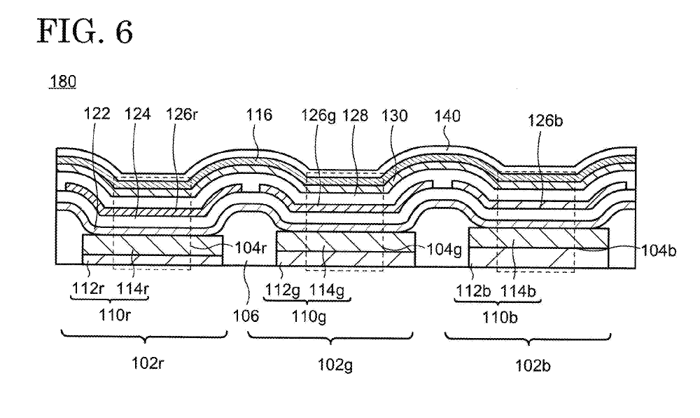

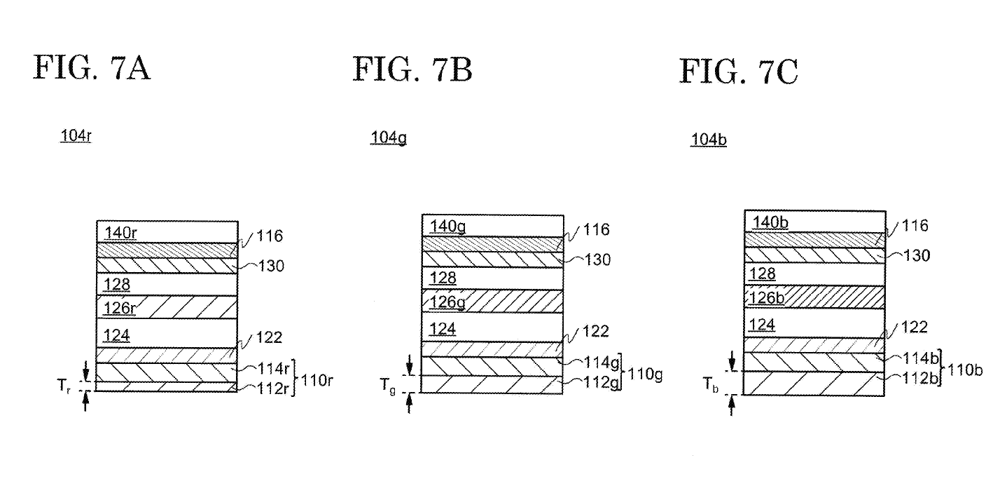

Similar to the display device 100, the first electrode 110 of each light-emitting element 104 of the display device 180 has the reflective electrode 112 and the transparent electrode 114 over the reflective electrode 112 as shown in FIG. 6. However, the reflective electrodes 112b, 112g, and 112r of the first to third light-emitting elements 104b, 104g, and 104r may have the same metal. Furthermore, the display device 180 may be configured so that the thicknesses of the reflective electrodes 112b, 112g, and 112r are different from one another or one of them is different from the other two. As shown in FIG. 7A to FIG. 7C, for example, the thicknesses of the reflective electrodes 112 are adjusted so that the following relationship is established:

T_{b}>T_{g}≥Tᵣ

where the thicknesses of the reflective electrodes 112b, 112g, and 112r are respectively T_{b}, T_{g}, and Tᵣ. The metals included in the reflective electrodes 112 can be selected from the metals exemplified in the First Embodiment.

The thickness T_{b} is selected so that the light generated in the emission layer 126b does not pass through the reflective electrode 112 and a reflectance as high as possible can be obtained in the first light-emitting element 104b. For example, the thickness T_{b} is equal to or more than 100 nm and equal to or less than 300 nm or equal to or more than 120 nm and equal to or less than 200 nm, and typically 130 nm. On the other hand, the thickness Tᵣ is selected so that the reflectance of the reflective electrode 112r is decreased by allowing part of the light generated in the emission layer 126r to pass through the reflective electrode 112r in the third light-emitting element 104r. For example, the thickness Tᵣ is equal to or more than 10 nm and equal to or less than 80 nm or equal to or more than 30 nm and equal to or less than 60 nm, and typically 50 nm. Similar to the third pixel 102r, the thickness T_{g} is selected so that the reflectance of the reflective electrode 112g is decreased by allowing part of the light generated in the emission layer 126g to pass through the reflective electrode 112g in the second light-emitting element 104g. However, the thickness of T_{g} is selected so that the reflectance of the reflective electrode 112g is equal to or higher than the reflectance of the reflective electrode 112r and smaller than the reflectance of the reflective electrode 112b. For example, the thickness T_{g} is equal to or more than 30 nm and equal to or less than 100 nm or equal to or more than 50 nm and equal to or less than 80 nm, and typically 70 nm. Hence, the following relationships are established:

R_{1b}>R_{1g}≥R₁ᵣ

T₁ᵣ≥T_{1g}≥T_{1g}

where the reflectances of the reflective electrodes 112b, 112g, and 112r are respectively R_{1b}, R_{1g}, and R₁ᵣ and the transmittances thereof are respectively T_{1b}, T_{1g}, and T₁ᵣ. T_{1g} may be 0 (zero).

Accordingly, similar to the First Embodiment, the behavior of the change of the emission intensity can be the same between the first to third light-emitting elements 104b, 104g, and 104r in the display device 180 even if the angle θ is varied. Moreover, the dependence of the chromaticity of x and y on angle θ can be decreased in the first to third light-emitting elements 104b, 104g, and 104r. As a result, it is possible to provide the light-emitting elements 104 having low viewing-angle dependence and excellent color purity of the emitted light. Moreover, the use of such light-emitting elements 104 allows production of a display device having small viewing-angle dependence and high color reproducibility.

### Fifth Embodiment

In the present embodiment, a manufacturing method of the display device 170 is explained. An explanation of the structures the same as those of the First to Fourth Embodiments may be omitted.

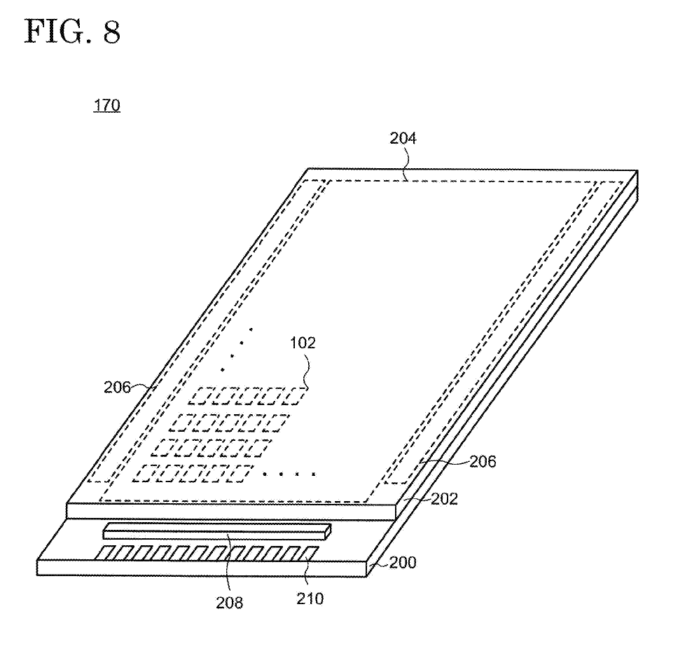

FIG. 8 is a schematic perspective view of the display device 170. The display device 170 possesses, over a substrate 200, the plurality of pixels 102, a display region 204 structured by the plurality of pixels 102, scanning-line driver circuits 206, and a data-line driver circuit 208. An opposing substrate 202 covers the display region 204. A variety of signals from an external circuit (not shown) is input to the scanning-line driver circuits 206 and the data-line driver circuit 208 through a connector such as a flexible printed circuit (FPC) connected to terminals 210 formed over the substrate 200, and each pixel 102 is controlled on the basis of these signals.

One or all of the scanning-line driver circuits 206 and the data-line driver circuit 208 may not be directly formed over the substrate 200. A driver circuit formed over a substrate (e.g., semiconductor substrate) different from the substrate 200 may be mounted on the substrate 200 or the connector, and the pixels 102 may be controlled with the driver circuit. In FIG. 8, an example is shown where the scanning-line driver circuits 206 prepared over the substrate 200 are covered by the opposing substrate 202, while the data-line driver circuit 208 is prepared over another substrate and then mounted on the substrate 200.

The substrate 200 and the opposing substrate 202 may be a substrate without flexibility or a substrate having flexibility. A structure may be employed in which a resin film or an optical film such as a circular polarizing plate is bonded instead of the opposing substrate 202. There is no particular limitation to the arrangement of the pixels 102, and a stripe arrangement, a delta arrangement, and the like may be applied.

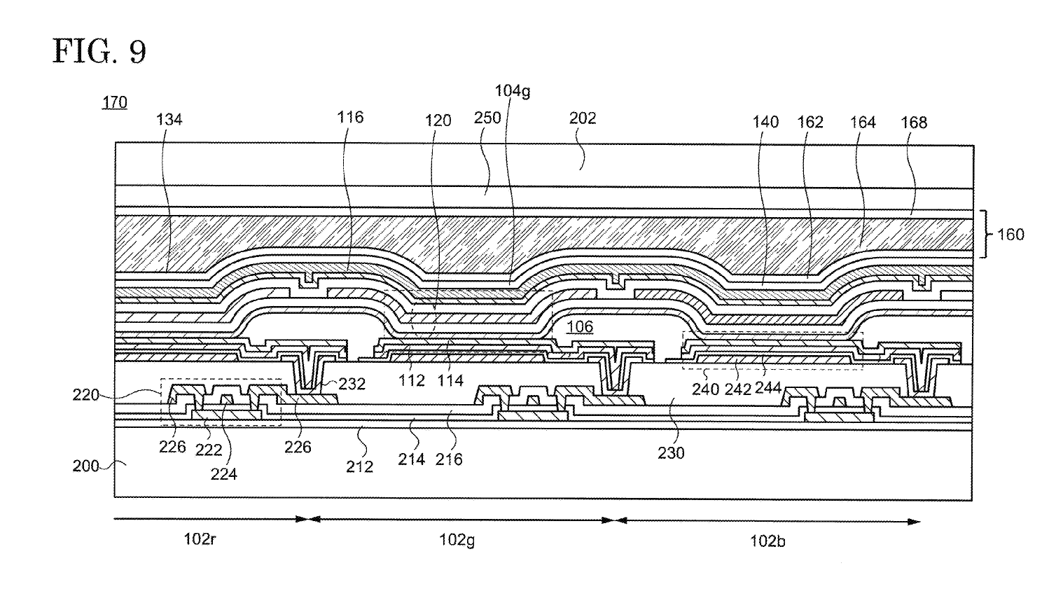

FIG. 9 shows a schematic cross-sectional view of the display device 170 including the first to third pixels 102b, 102g, and 102r. The first to third pixels 102b, 102g, and 102r each possess, over the substrate 200, elements such as a transistor 220, the light-emitting element 104 electrically connected to the transistor 220, and a supplementary capacitor 240 through a base film 212. FIG. 9 shows an example in which one transistor 220 and one supplementary capacitor 240 are disposed in each pixel 102. However, each pixel 102 may have a plurality of transistors and a plurality of capacitor elements. The structure of the light-emitting element 104 is the same as that described in the First Embodiment. Hereinafter, the manufacturing method of the display device 100 is explained.

### 1. Transistor

First, as shown in FIG. 10A, the base film 212 is formed over the substrate 200. The substrate 200 has a function to support semiconductor elements included in the display region 204, such as the transistor 220, the light-emitting element 104, and the like. The substrate 200 may include glass, quartz, plastics, a metal, ceramics, and the like.

When flexibility is provided to the display device 100, a base material (not illustrated) is formed over the substrate 200, and then the base film 212 is provided. In this case, the substrate 200 may be called a supporting substrate or a carrier substrate. The base material is an insulating film with flexibility and may include a material selected from polymer materials exemplified by a polyimide, a polyamide, a polyester, and a polycarbonate. The base material can be formed by applying a wet-type film-forming method such as a printing method, an ink-jet method, a spin-coating method, and a dip-coating method or a lamination method.

The base film 212 is a film having a function to prevent impurities such as an alkaline metal from diffusing to the transistor 220 and the like from the substrate 200 (and the base material) and may include a silicon-containing inorganic compound such as silicon nitride, silicon oxide, silicon nitride oxide, and silicon oxynitride. The base film 212 can be formed to have a single-layer or stacked-layer structure by applying a chemical vapor deposition method (CVD method), a sputtering method, or the like.

Next, a semiconductor film 222 is formed (FIG. 10A). The semiconductor film 222 may contain Group 14 elements such as silicon or an oxide (hereinafter, referred to as a semiconductor oxide) exhibiting semiconductor properties. A Group 13 element such as indium and gallium or a Group 12 element such as zinc may be included as an oxide semiconductor, and a mixed oxide (IGO) of indium and gallium and a mixed oxide (IGZO) of indium, gallium, and zinc are exemplified. Crystallinity of the semiconductor film 222 is not limited, and the semiconductor film 222 may include a crystal state of a single crystalline, polycrystalline, microcrystalline, or amorphous state.

When the semiconductor film 222 includes silicon, the semiconductor film 222 may be prepared with a CVD method by using a silane gas and the like as a raw material. A heat treatment or application of light such as a laser may be performed on amorphous silicon obtained to conduct crystallization. When the semiconductor film 222 includes an oxide semiconductor, the semiconductor film 222 can be formed by utilizing a sputtering method and the like.

Next, a gate insulating film 214 is prepared so as to cover the semiconductor film 222 (FIG. 10A). The gate insulating film 214 may also include a silicon-containing inorganic compound and can be prepared with a CVD method or a sputtering method. The gate insulating film 214 may have a single-layer structure or a stacked-layer structure.

Next, a gate (gate electrode) 224 is formed over the gate insulating film 214 with a sputtering method or a CVD method (FIG. 10B). The gate 224 may be formed with a metal such as titanium, aluminum, copper, molybdenum, tungsten, tantalum or an alloy thereof so as to have a single-layer or stacked-layer structure. For example, a structure in which a highly conductive metal such as aluminum and copper is sandwiched by a metal with a relatively high melting point, such as titanium, tungsten, and molybdenum, can be employed.

Next, an interlayer film 216 is formed over the gate 224 (FIG. 10B). The interlayer film 216 may have a single-layer or stacked layer structure, may include a silicon-containing inorganic compound, and may be prepared with a CVD method or a sputtering method. When the interlayer film 216 has a stacked structure, a layer including an inorganic compound may be stacked after forming a layer including an organic compound, for example. Although a detailed explanation is omitted, doping may be conducted on the semiconductor film 222 to form source/drain regions, low-concentration impurity regions, and the like.

Next, etching is performed on the interlayer film 216 and the gate insulating film 214 to form openings 228 reaching the semiconductor film 222 (FIG. 100). The openings 228 can be prepared, for example, by conducting plasma etching in a gas including a fluorine-containing hydrocarbon.

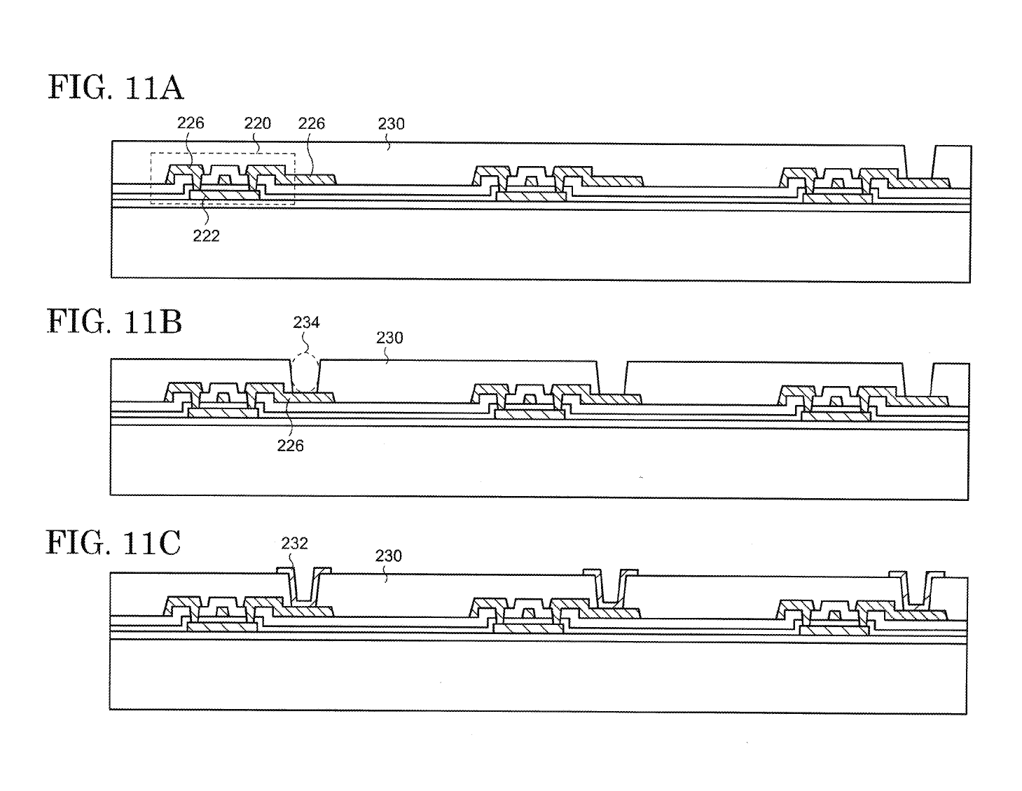

Next, a metal film is formed to cover the openings 228 and processed with etching to form a source/drain (source/drain electrodes) 226 (FIG. 11A). Similar to the gate 224, the metal film may include a variety of metals and have a single-layer or stacked layer structure. Through the aforementioned processes, the transistor 220 is fabricated. In the present embodiment, the transistor 220 is illustrated as a top-gate type transistor. However, there is no limitation to the structure of the transistor 220, and the transistor 220 may be a bottom-gate type transistor, a multi-gate type transistor having a plurality of gates 224, or a dual-gate type transistor having a structure in which the semiconductor film 222 is sandwiched by two gates 224. Moreover, there is no limitation to a vertical relationship between the source/drain 226 and the semiconductor film 222.

### 2. Supplementary Capacitor and Light-Emitting Element

Next, a leveling film 230 is formed so as to cover the transistor 220 (FIG. 11A). The leveling film 230 has a function to absorb depressions, projections, and inclinations caused by the transistor 220 and the like and provide a flat surface. The leveling film 230 can be prepared with an organic insulator. As an organic insulator, a polymer material such as an epoxy resin, an acrylic resin, a polyimide, a polyamide, a polyester, a polycarbonate, and a polysiloxane is represented. The leveling film 230 can be formed with the aforementioned wet-type film-forming method and the like.

After that, etching is performed on the leveling film 230 to form an opening 234 exposing one of the source/drain 226 of the transistor 220 (FIG. 11B). A connection electrode 232 is prepared so as to cover this opening 234 and be in contact with one of the source/drain 226 of the transistor 220 (FIG. 11C). The connection electrode 232 may be formed by using a conductive oxide such as ITO and IZO with a sputtering method or the like. Formation of the connection electrode 232 is optional. Deterioration of a surface of the source/drain 226 can be avoided in the following processes by forming the connection electrode 232, by which generation of contact resistance between the source/drain 226 and the first electrode 106 can be suppressed.

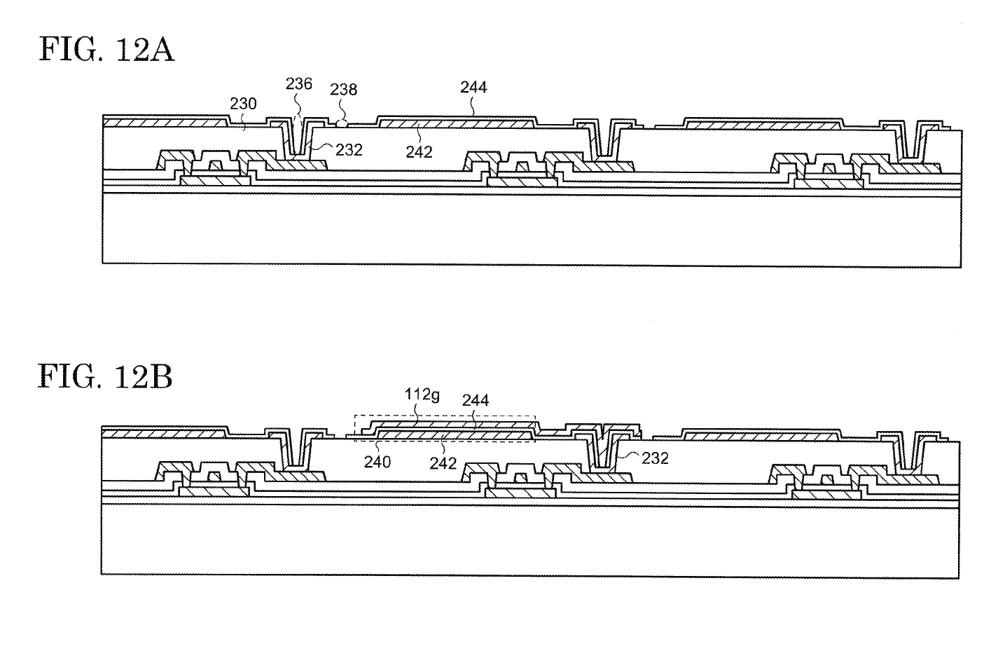

Next, a metal film is formed over the leveling film 230 and processed with etching to form one of the electrodes 242 of the supplementary capacitance 240 (FIG. 12A). Similar to the conductive film used for the formation of the source/drain 226, the metal film used here may have a single layer structure or a stacked layer structure, and a three-layer structure of molybdenum/aluminum/molybdenum may be employed, for example.

Next, an insulating film 244 is formed over the leveling film 230 and the electrode 242 (FIG. 12A). The insulating film 244 not only functions as a protection film for the transistor 220 but also serves as a dielectric in the supplementary capacitors 240. Therefore, it is preferred to use a material with relatively high permittivity. The insulating film 244 may include a silicon-containing inorganic compound and may be formed by applying a CVD method or a sputtering method. After that, openings 236 and 238 are provided in the insulating film 244 (FIG. 12A). The former exposes a bottom surface of the connection electrode 232 to provide electrical connection between the first electrode 106 formed later and the connection electrode 232. The latter is an opening to abstract, through the partition wall 106, water and gas eliminated from the leveling film 230 in a heating process and the like performed after the formation of the partition wall 106.

Next, the reflective electrode 112g of the first electrode 110 is formed to cover the opening 236 as shown in FIG. 12B. For example, a metal film including aluminum is formed over the almost entire surface of the substrate 200 by using a sputtering method or a CVD method and then processed with etching to selectively fabricate the reflective electrode 112g in the second pixel 102g. The reflective electrode 112 is electrically connected to the connection electrode 232 in the opening 236.

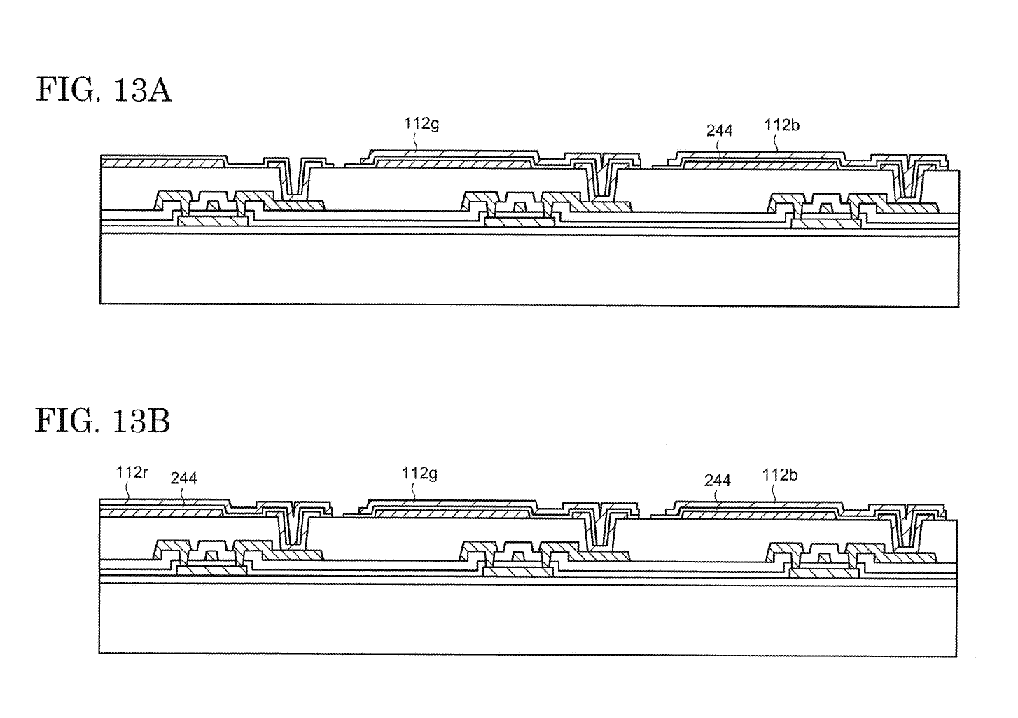

Next, the reflective electrode 112b of the first pixel 102b is formed as shown in FIG. 13A. The reflective electrode 112b is prepared so as to contain a metal different from the metal included in the reflective electrode 112g. After that, the reflective electrode 112r of the third pixel 102r is formed as shown in FIG. 13B. The reflective electrode 112r is prepared so as to contain a metal different from the metals included in the reflective electrodes 112b and 112g. Note that the formation order of the reflective electrodes 112 is not limited to the above order and may be arbitrarily determined. When only one of the reflective electrodes 112b, 112g, and 112r has a metal different from the metal of the other two, the two reflective electrodes 112 having the same metal may be simultaneously formed.

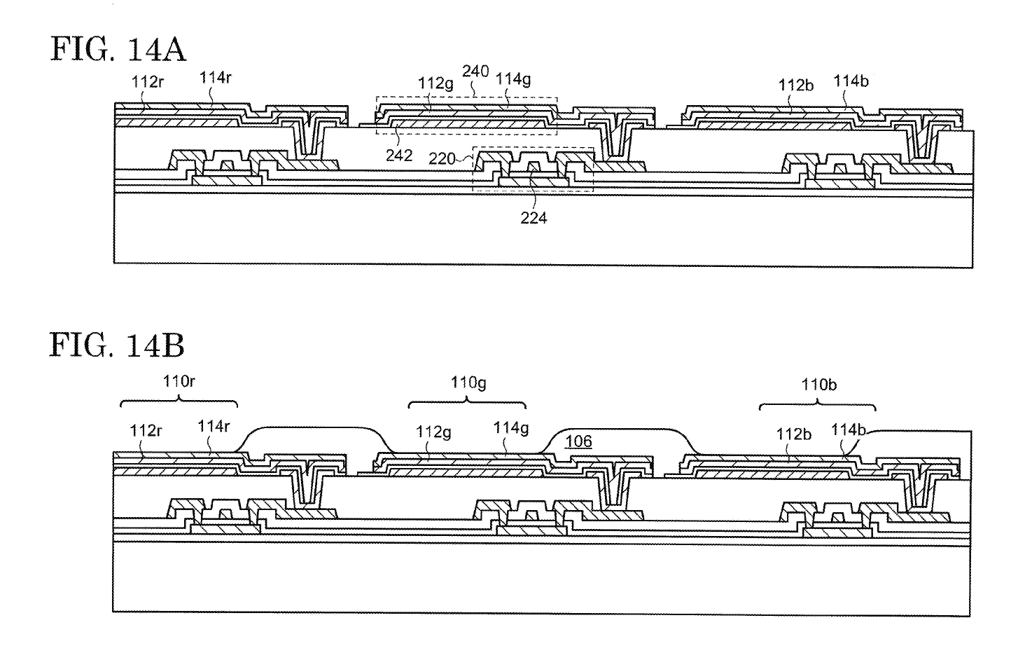

Next, the transparent electrodes 114 are fabricated so as to cover the reflective electrodes 112b, 112g, and 112r (FIG. 14A and FIG. 14B). The transparent electrodes 114 can be formed with a sputtering method, for example. As shown in FIG. 14, the reflective electrodes 112 and the transparent electrodes 114 may be formed so that side surfaces of the reflective electrode 112 and the transparent electrode 114 exist in the same plane in each pixel 102. However, the transparent electrode 114 may be formed to cover the side surface of the reflective electrode 112.

In the present embodiment, an example is demonstrated in which the transparent electrodes 114b, 114g, and 114r are formed after forming the reflective electrodes 112b, 112g, and 112r. However, the formation order of these electrodes is not limited. For example, the reflective electrode 112 and the transparent electrode 114 of one pixel 102 is first fabricated, and then the reflective electrodes 112 and the transparent electrodes 114 of other pixels 102 may be sequentially formed. In this case, the reflective electrodes 112 and the transparent electrodes 114 can be sequentially formed, by which oxidation of surfaces of the reflective electrodes 112 can be inhibited.

The supplementary capacitor 240 is formed by the first electrode 110, the insulating film 244, and the electrode 242. A potential of the gate 224 of the transistor 220 can be maintained for a longer time by forming the supplementary capacitor 240. The structure of the first electrode 110 is the same as that described in the First Embodiment, and the first electrode 110 can be formed by using a sputtering method, a CVD method, or the like.

Next, the partition wall 106 is formed so as to cover the edge portions of the first electrodes 110 (FIG. 14B). The partition wall 106 may be prepared with a wet-type film-forming method by using an epoxy resin, an acrylic resin, or the like.

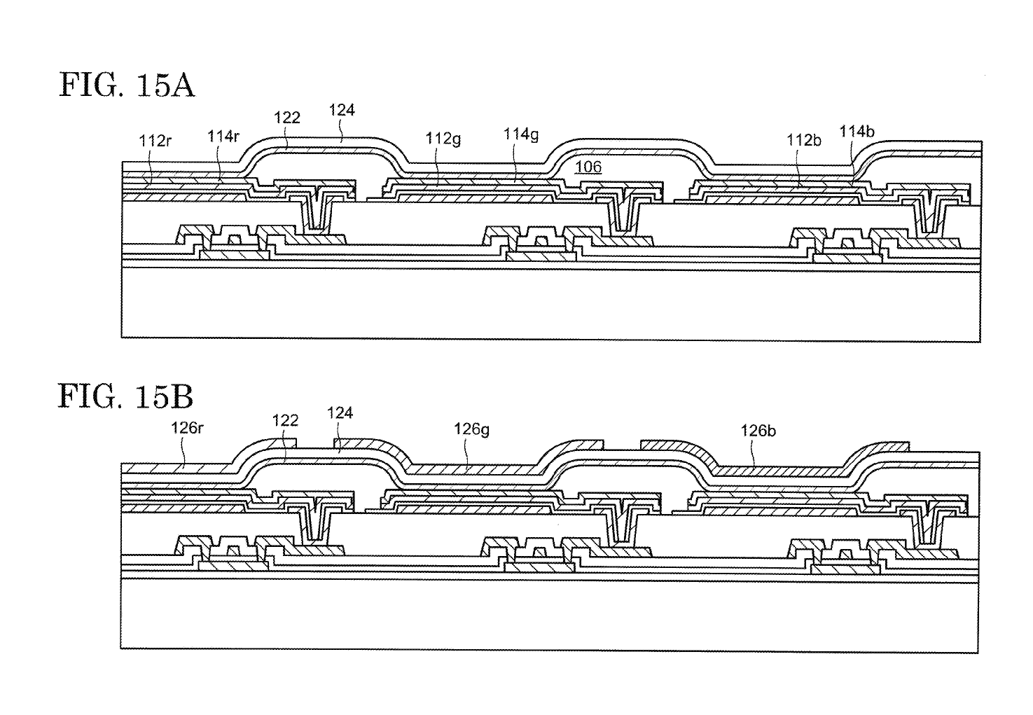

Next, the electroluminescence layer 120 and the second electrode 116 are formed so as to cover the first electrodes 110 and the partition wall 106. The structures of these elements are the same as those described in the First Embodiment. Specifically, the hole-injection layer 122 is first formed to cover the transparent electrodes 114 of the first electrodes 110 and the partition wall 106, and then the hole-transporting layer 124 is prepared over the hole-injection layer 122 (FIG. 15A). After that, the emission layers 126 are formed over the hole-transporting layer 124 (FIG. 15B). In the present embodiment, the emission layers 126b, 126g, and 126r having different structures or including different materials between the adjacent pixels 102 are formed. In this case, the materials to be included in the emission layers 126b, 126g, and 126r respectively corresponding to the first pixel 102b, the second pixel 102g, and the third pixel 102r may be sequentially deposited with an evaporation method. Alternatively, the emission layers 126b, 126g, and 126r may be independently formed with an ink-jet method.

Although not shown, it is possible to prepare the emission layer 126 so as to have the same structure and the same material in the first to third pixels 102b, 102g, and 102r. In this case, the emission layer 126 is prepared continuously in the first to third pixels 102b, 102g, and 102r and shared by the first to third pixels 102b, 102g, and 102r. In this case, the emission layer 126 may be configured to give white emission.

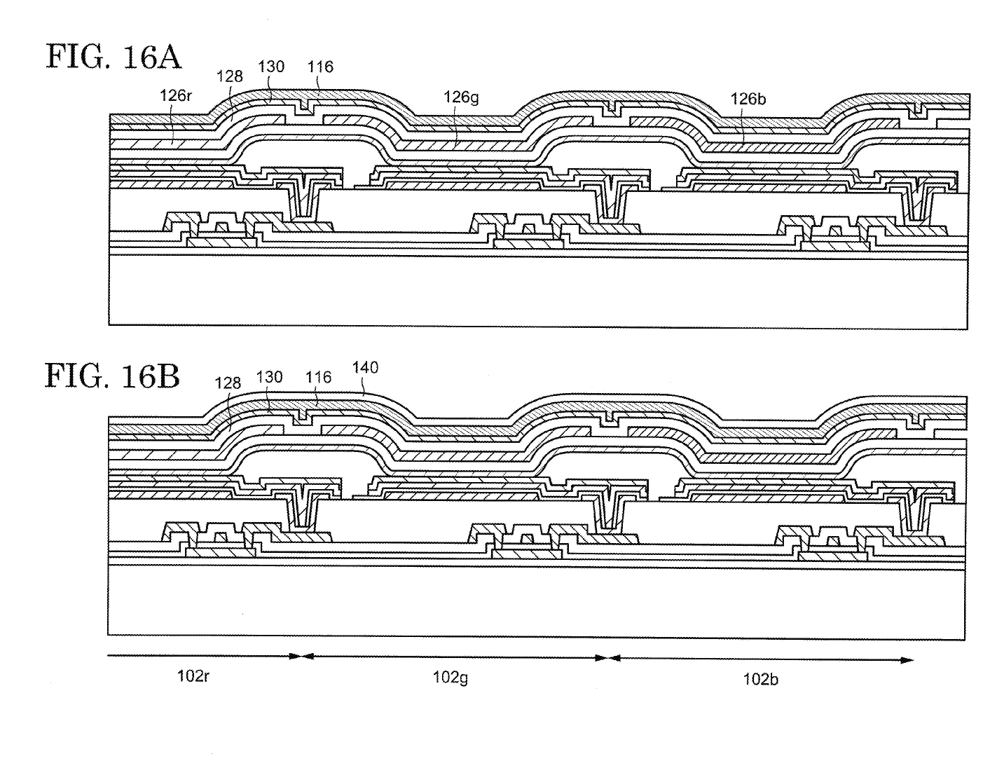

The electron-transporting layer 128 and the electron-injection layer 130 are successively formed over the emission layers 126, and the second electrode 116 is fabricated over the electron-injection layer 130 (FIG. 16A). The second electrode 116 is also prepared by using a sputtering method or an evaporation method. Through these processes, the supplementary capacitors 240 and the light-emitting elements 104 are fabricated.

### 3. Optical Adjustment Layer

Next, the optical adjustment layer 140 is formed over the second electrode 116 (FIG. 16B). The optical adjustment layer 140 may be formed with a wet-type film-forming method or a dry-type film-forming method.

### 4. Other Structures

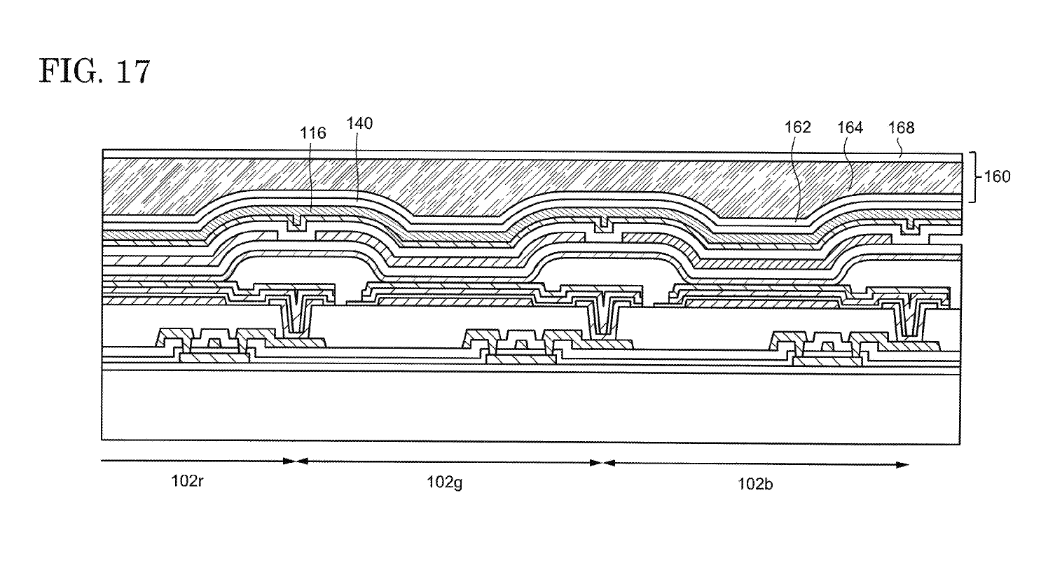

The display device 170 may having a passivation film (sealing film) and the like as an optional structure. The passivation film may be composed of a single layer or a plurality of layers. For example, the passivation film 160 in which a first layer 162, a second layer 164, and a third layer 166 are stacked may be formed as shown in FIG. 17.

In this case, the first layer 162 is first formed over the optical adjustment layer 140. The first layer 162 may include a silicon-containing inorganic compound or the like and may be prepared with a CVD method or a sputtering method, for example.

Next, the second layer 164 is formed. The second layer 164 may contain an organic resin including an acrylic resin, a polysiloxane, a polyimide, a polyester, and the like. Furthermore, as shown in FIG. 17, the second layer 164 may be formed at a thickness so that depressions and projections caused by the partition wall 106 and the like are absorbed, and a flat surface is provided. The second layer 164 may be formed by a wet-type film-forming method such as an ink-jet method. Alternatively, the second layer 164 may be prepared by atomizing or vaporizing oligomers serving as a raw material of the aforementioned polymer material at a reduced pressure, spraying the first layer 162 with the oligomers, and then polymerizing the oligomers.

After that, the third layer 168 is formed. The third layer 168 may have the same structure as the first layer 162 and can be formed with the same method as that of the first layer 162. Through these processes, the passivation film 160 is fabricated. When the passivation film 160 is a single layer, the passivation film 160 can be formed with a material the same as that of the first layer 162. When the passivation film 160 is composed of a plurality of layers, the uppermost layer and the lowest layer may be formed with a material the same as that of the first layer 162.

After that, the opposing substrate 202 is fixed through the adhesion layer 250 (FIG. 9). The opposing substrate 202 may include the same material as the substrate 200. When flexibility is provided to the display device 170, a polymer material such as a polyolefin and a polyimide can be applied for the opposing substrate 202 in addition to the aforementioned polymer materials. In this case, the elements such as the transistor 220 and the light-emitting element 104 are fabricated over a base material formed over the substrate 200 as described above, and then the opposing substrate 202 with flexibility is fixed thereover. After that, an interface between the substrate 200 and the base material is irradiated with light such as a laser to reduce adhesion between the substrate 200 and the base material, and then the substrate 200 is physically peeled off, leading to the formation of the flexible display device 170.

Although not shown, a polarizing plate (circular polarizing plate) may be formed instead of the opposing substrate 202 as described above. Alternatively, a polarizing plate may be arranged over or under the opposing substrate 202. In addition, an electrode, a functional film including an electrode, or a functional substrate (e.g., a touch panel) may be disposed.

As described above, in the display devices disclosed in the present specification, the reflectances of the reflective electrodes 112 are individually varied in the light-emitting elements 104. Therefore, even if the emission intensity of the light-emitting elements 104 is changed with the change of the angle θ, the behavior of this change can be the same between the first to third light-emitting elements 104b, 104g, and 104r. Moreover, the dependence of the chromaticity of x and y on angle θ can be decreased in each light-emitting element 104. As a result, it is possible to provide the light-emitting elements 104 having low viewing-angle dependence and excellent color purity of the emitted light. Moreover, the use of such light-emitting elements 104 allows production of a display device having small viewing-angle dependence and high color reproducibility.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process is included in the scope of the present invention as long as they possess the concept of the present invention.

In the specification, although the cases of the organic EL display device are exemplified, the embodiments can be applied to any kind of display devices of the flat panel type such as other self-emission type display devices, liquid crystal display devices, and electronic paper type display device having electrophoretic elements and the like. In addition, it is apparent that the size of the display device is not limited, and the embodiment can be applied to display devices having any size from medium to large.

It is properly understood that another effect different from that provided by the modes of the aforementioned embodiments is achieved by the present invention if the effect is obvious from the description in the specification or readily conceived by persons ordinarily skilled in the art.

What is claimed is:

1. A display device comprising:
a first light-emitting element and a second light-emitting element each comprising:
a first electrode;
a second electrode over and in contact with the first electrode;
an electroluminescence layer over the second electrode; and
a third electrode over the electroluminescence layer, the third electrode being shared by the first light-emitting element and the second light-emitting element,
wherein the first electrode of the first light-emitting element includes a first metal,
the first electrode of the second light-emitting element includes a second metal,
the first electrode has a higher reflectance than the second electrode, and
the first metal is different in reflectance from the second metal.

2. The display device according to claim 1,
wherein an emission peak wavelength of the first light-emitting element is shorter than an emission peak wavelength of the second light-emitting element, and
the first metal has a higher reflectance than the second metal.

3. The display device according to claim 1,
wherein, in each of the first light-emitting element and the second light-emitting element, the electroluminescence layer has an emission layer over the second electrode via a hole-transporting region which is configured so that an optical distance from an upper surface of the first electrode to a point arbitrarily selected in the emission layer is an integral multiple of one half of an emission peak wavelength of the electroluminescence layer.

4. The display device according to claim 1,
wherein, in each of the first light-emitting element and the second light-emitting element, the electroluminescence layer is configured so that a summation of an optical distance of the electroluminescence layer and an optical distance of the second electrode is an integral multiple of one half of an emission peak wavelength of the electroluminescence layer.

5. The display device according to claim 1, further comprising an optical adjustment layer over and in contact with the third electrode, wherein the optical adjustment layer is configured so that a thickness thereof over the first light-emitting element is smaller than a thickness thereof over the second light-emitting element.

6. The display device according to claim 1, further comprising a third light-emitting element comprising:
a first electrode;
a second electrode over and in contact with the first electrode;
an electroluminescence layer over the second electrode; and
a third electrode over the electroluminescence layer, the third electrode being shared by the first light-emitting element, the second light-emitting element, and the third light-emitting element,
wherein the first electrode of the third light-emitting element has a third metal different from the first metal.

7. The display device according to claim 6, wherein the third metal is different from the second metal.

8. The display device according to claim 6,
wherein an emission peak wavelength of the third light-emitting element is longer than an emission peak wavelength of the first light-emitting element and an emission peak wavelength of the second light-emitting element, and
a reflectance of the second metal is lower than a reflectance of the first metal and equal to or higher than a reflectance of the third metal.

9. A display device comprising:
a first light-emitting element and a second light-emitting element each comprising:
a first electrode;
a second electrode over and in contact with the first electrode;
an electroluminescence layer over the second electrode; and
a third electrode over the electroluminescence layer, the third electrode being shared by the first light-emitting element and the second light-emitting element,
wherein the first electrodes of the first light-emitting element and the second light-emitting elements are different in thickness from each other.

10. The display device according to claim 9,
wherein an emission peak wavelength of the first light-emitting element is shorter than an emission peak wavelength of the second light-emitting element, and
the first electrode of the first light-emitting element is thicker than the first electrode of the second light-emitting element.

11. The display device according to claim 9,
wherein an emission peak wavelength of the first light-emitting element is shorter than an emission peak wavelength of the second light-emitting element, and
the first electrode of the first light-emitting element has a higher reflectance than the first electrode of the second light-emitting element.

12. The display device according to claim 9,
wherein an emission peak wavelength of the first light-emitting element is shorter than an emission peak wavelength of the second light-emitting element, and
the first electrode of the first light-emitting element has a lower transmittance than the first electrode of the second light-emitting element.

13. The display device according to claim 9, wherein, in each of the first light-emitting element and the second light-emitting element, the electroluminescence layer has an emission layer over the second electrode via a hole-transporting region which is configured so that an optical distance from an upper layer of the first electrode to a point arbitrarily selected in the emission layer is an integral multiple of one half of an emission peak wavelength of the electroluminescence layer.

14. The display device according to claim 9, wherein, in each of the first light-emitting element and the second light-emitting element, the electroluminescence layer is configured so that a summation of an optical distance of the electroluminescence layer and an optical distance of the second electrode is an integral multiple of one half of an emission peak wavelength of the electroluminescence layer.

15. The display device according to claim 9, further comprising an optical adjustment layer over and in contact with the third electrode, wherein the optical adjustment layer is configured so that a thickness thereof over the first light-emitting element is smaller than a thickness thereof over the second light-emitting element.

16. The display device according to claim 9, further comprising a third light-emitting element comprising:
a first electrode;
a second electrode over and in contact with the first electrode;
an electroluminescence layer over the second electrode; and
a third electrode over the electroluminescence layer, the third electrode being shared by the first light-emitting element, the second light-emitting element, and the third light-emitting element,
wherein the first electrode of the third light-emitting element and the first electrode of the first light-emitting element are different in thickness from each other.

17. The display device according to claim 16, wherein the first electrodes of the first light-emitting element, the second light-emitting element, and the third light-emitting element have the same metal.

18. The display device according to claim 16,
wherein an emission peak wavelength of the third light-emitting element is longer than an emission peak wavelength of the first light-emitting element and an emission peak wavelength of the second light-emitting element, and
the first electrode of the third light-emitting element is thinner than the first electrode of the first light-emitting element.

19. The display device according to claim 16,
wherein an emission peak wavelength of the third light-emitting element is longer than an emission peak wavelength of the first light-emitting element and an emission peak wavelength of the second light-emitting element, and
the first electrode of the third light-emitting element has a lower reflectance than the first electrode of the first light-emitting element.

20. The display device according to claim 16,
wherein an emission peak wavelength of the third light-emitting element is longer than an emission peak wavelength of the first light-emitting element and an emission peak wavelength of the second light-emitting element, and
the first electrode of the third light-emitting element has a higher transmittance than the first electrode of the first light-emitting element.
